(19) United States
(12) Patent Application Publication
(10) Pub. No.: US 2021/0202477 A1
(43) Pub. Date: Jul. 1, 2021

(54) THREE-DIMENSIONAL DEVICE AND MANUFACTURING METHOD THEREOF

(71) Applicants: ADVANTEST CORPORATION, Tokyo (JP); Tokyo Institute of Technology, Tokyo (JP)

(72) Inventors: Shinji SUGATANI, Saitama (JP); Takayuki OHBA, Tokyo (JP)

(21) Appl. No.: 16/953,350

(22) Filed: Nov. 20, 2020

(30) Foreign Application Priority Data
Dec. 25, 2019 (JP) 2019-234428

(51) Int. Cl. H01L 27/06; H01L 25/065; H01L 23/538; H01L 21/66; G11C 29/12; H01L 21/50

(52) U.S. Cl. CPC H01L 27/0688; H01L 25/0657; H01L 23/5384; H01L 21/50; H01L 23/5386; H01L 22/14; G11C 29/12; H01L 23/5385

(57) ABSTRACT

When testing a memory chip, the memory chip is determined to be defective if even a portion of the memory chip is defective, and is discarded, which lowers the yield of the three-dimensional memory device. A three-dimensional device is provided comprising a plurality of stacked circuit chips each having one or more circuit blocks in each of a plurality of divided regions obtained by dividing a circuit plane and an interconnect portion communicatively connected, for each group of circuit blocks included in each of the divided regions overlapping in a stacking direction in the plurality of circuit chips, to a predetermined number of circuit blocks sorted from the circuit blocks within the group.

The contents of the following Japanese patent application(s) are incorporated herein by reference:
No. 2019-234428 filed in JP on Dec. 25, 2019.

### TECHNICAL FIELD

The present invention relates to a three-dimensional device and a manufacturing method thereof

### RELATED ART

Traditionally, when manufacturing three-dimensional memory devices by stacking a plurality of memory chips, memory chips are tested before stacking and the non-defective ones are sorted (see Non-Patent Document 1, for example).
Non-Patent Document 1: IEEE Design & Test, Volume: 34, Hongshin Jun, et al, High-Bandwidth Memory (HBM) Test Challenges and Solutions

### SUMMARY

When testing a memory chip, the memory chip is determined to be defective if even a portion of the memory chip is defective, and the memory chip is discarded, which lowers the yield of the three-dimensional memory device.

To solve the above-described problem, a three-dimensional device is provided in a first aspect of the present invention. The three-dimensional device may include a plurality of stacked circuit chips each having one or more circuit blocks in each of a plurality of divided regions obtained by dividing a circuit plane. The three-dimensional device may include an interconnect portion communicatively connected, for each group of circuit blocks included in each of the divided regions overlapping in a stacking direction in the plurality of circuit chips, to a predetermined number of circuit blocks sorted from the circuit blocks within the group.

The interconnect portion may include through wiring which passes through at least one circuit chip and extends in the stacking direction of the plurality of circuit chips.

At least one of the groups of circuit blocks may include at least one circuit block determined to be defective, and the predetermined number of circuit blocks determined to be non-defective.

The at least one circuit block determined to be defective may be disconnected from at least one the interconnect portion and a power source.

The three-dimensional device may include a control chip being connected to the interconnect portion below or above the circuit chip that is configured to control each circuit block.

The control chip may include an address register configured to set an address associated with each of the plurality of circuit blocks. The control chip may include a command receiving section configured to receive a command including specification of an address for the three-dimensional device. The control chip may include a command processing section configured to access the circuit block associated with the address specified by the command, in response to receiving the command.

Each of the plurality of circuit blocks may include an address register configured to set an address associated with each of the plurality of circuit blocks. Each of the plurality of circuit blocks may include a command receiving section configured to receive a command via the interconnect portion. Each of the plurality of circuit blocks may include a command processing section for executing a process specified by the command, in response to receiving the command.

An address setting corresponding to the circuit block in the address register may be rewritable.

Each of the plurality of circuit blocks may be a memory block.

In a second aspect of the present invention, a manufacturing method for a three-dimensional device is provided. The manufacturing method may include forming a wafer having arranged thereon a circuit chip region with one or more circuit blocks in each of a plurality of divided regions obtained by dividing a circuit plane. The manufacturing method may include testing each of the circuit blocks on the wafer. The manufacturing method may include stacking a plurality of the wafers. The manufacturing method may include forming a plurality of stacked circuit chips by dicing the plurality of stacked wafers in each circuit chip region. The manufacturing method may include, before or after the dicing, forming an interconnect portion communicatively connected, for each group of circuit blocks included in each of the divided regions overlapping in a stacking direction, to a predetermined number of circuit blocks sorted from the circuit blocks within the group based on a result of the test.

Stacking the plurality of wafers may include selecting a combination of the wafers to be stacked, based on the number of the three-dimensional devices in which at least the predetermined number of circuit blocks determined to be non-defective by the test are stacked, for each group of circuit blocks included in each of the divided regions overlapping in a stacking direction, based on a location in the wafer of the circuit block determined to be non-defective by the test.

The summary clause does not necessarily describe all necessary features of the embodiments of the present invention. The present invention may also be a sub-combination of the features described above.

### BRIEF DESCRIPTION OF THE DRAWINGS

FIG. 1 is a schematic view showing an exemplary configuration of an apparatus 10 of the present embodiment.

FIG. 2 shows an illustration of one example of a plurality of stacked circuit chips 100 of the present embodiment.

FIG. 3 shows one example of a circuit configuration of a three-dimensional device 50 of the present embodiment.

FIG. 4 shows one example of a correspondence table of memory block and addresses.

FIG. 5 shows another example of a circuit configuration of the three-dimensional device 50 of the present embodiment.

FIG. 6 shows a manufacturing flow for the three-dimensional device 50 of the present embodiment.

### DESCRIPTION OF EXEMPLARY EMBODIMENTS

Hereinafter, the present invention will be described through embodiments of the invention. However, the following embodiments do not limit the invention defined in the claims. Also, all combinations of features described in the embodiments are not necessarily essential to solutions of the invention.

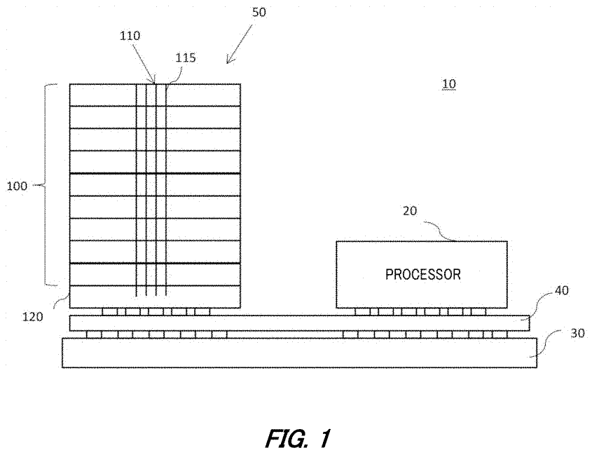

FIG. 1 is a schematic view showing an exemplary configuration of an apparatus 10 of the present embodiment. The apparatus 10 is a device equipped with an HBM (High-Bandwidth Memory) as an example. The apparatus 10 writes data onto a three-dimensional device 50 or reads data within the three-dimensional device 50, according to a command from a processor 20. The apparatus 10 includes the processor 20, a substrate 30, an interposer 40, and the three-dimensional device 50.

The processor 20 is connected to the top surface side of the interposer 40, and may be at least one of a central processing unit (CPU), a graphics processor unit(GPU), and a FPGA (Field Programmable Gate Array), as an example. The processor 20 communicates with the three-dimensional device 50 or an external device via the interposer 40.

The top surface of the substrate 30 is connected to the lower surface side of the interposer 40, and the lower surface of the substrate may include a terminal for connection with the external device. The top surface side of the interposer 40 is connected to the three-dimensional device 50. The interposer 40 has electrodes formed on its top surface and lower surface. The interposer 40 includes internal wiring that is connected to the electrodes connected to each of the processor 20, the substrate 30, and the three-dimensional device 50, and interconnects these components.

The three-dimensional device 50 communicates with the processor 20 via the interposer 40, and operates as a memory portion of the apparatus 10. The three-dimensional device 50 includes a plurality of circuit chips 100, an interconnect portion 110, and a control chip 120.

The plurality of circuit chips 100 are each connected to the interconnect portion 110 and are stacked on each other. The circuit chip 100 is a semiconductor memory chip such as a DRAM (Dynamic Random Access Memory) chip, as an example. Data is written to and read from each of the plurality of circuit chips 100, according to signals from the control chip 120 via the interconnect portion 110.

The interconnect portion 110 is connected to the control chip 120, and enables communication between the control chip 120 and each circuit chip 100. As an example, the interconnect portion 110 may include a command line for communicating a command, an address line for communicating an address, and a data line for communicating data. The interconnect portion 110 includes through wiring 115 which passes through at least one circuit chip 100 and extends in the stacking direction of the plurality of circuit chips 100. The through wiring 115 includes a TSV (Through-Silicon Via) which passes through each circuit chip 100, a microbump for connecting circuit chips 100 to each other, and the like, for example The through wiring 115 may pass through all of the circuit chips 100 to extends in the stacking direction to the control chip 120 and connect to all of the circuit chips 100, thereby connecting each circuit chip 100 to the control chip 120. Note that, the through wiring 115 may not include a microbump, in which case, the through wiring 115 may connect the plurality of circuit chips 100 only with a conductive material filled in the TSV, for example.

The control chip 120 is placed on the lower surface side of the circuit chip 100 at the lower end, and is connected to the interposer 40 via a microbump or the like. The control chip 120 receives a command from the processor 20 via the interposer 40 and communicates with each circuit chip 100 via the interconnect portion 110, to control each circuit chip 100 to execute an operation according to the command (for example, writing or reading of data).

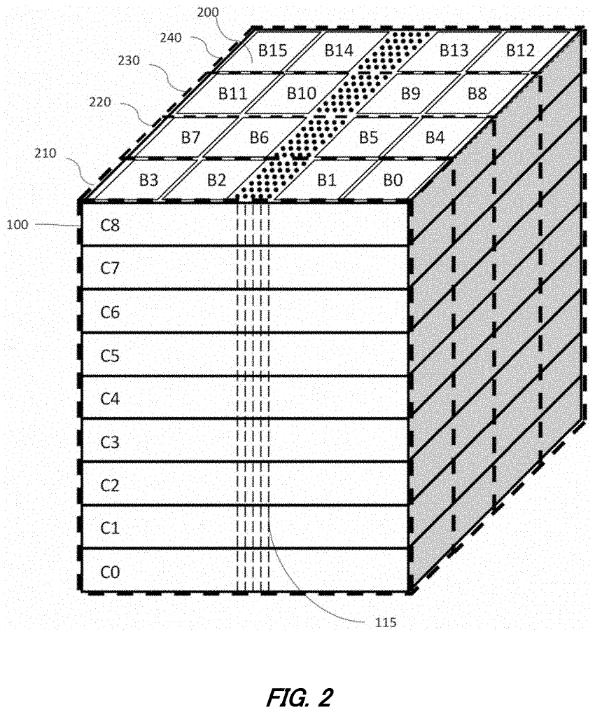

FIG. 2 shows an illustration of a plurality of stacked circuit chips 100 of the present embodiment. In FIG. 2, the through wiring 115 of the interconnect portion 110 formed inside the circuit chip 100 is indicated with dashed lines. Also, in FIG. 2, the plurality of circuit chips 100 is depicted as circuit chips C0 to C8.

The plurality of stacked circuit chips C0 to C8 each includes one or more memory blocks B0 to B15 in each of the plurality of divided regions 210 to 240 obtained by dividing a circuit plane 200. The circuit plane 200 is the top surface for each of the plurality of circuit chips C0 to C8. The plurality of memory blocks B0 to B15 of the circuit chips C0 to C8 may each be connected to the interconnect portion 110. Here, the memory blocks B0 to B15 may include one or more memory elements (for example, an element storing one bit).

In FIG. 2, the plurality of circuit chips C0 to C8 each includes the same number of memory blocks B0 to B15 in the same arrangement. Memory blocks at a location overlapping in the stacking direction formed in different circuit chips C0 to C8 are given the same reference number. Also, in FIG. 2, there are four divided regions 210 to 240. For example, the divided region 210 includes a group of respective memory blocks B0 to B3 of the circuit chips C0 to C8, the divided region 220 includes a group of respective memory blocks B4 to B7 of the circuit chips C0 to C8, the divided region 230 includes a group of respective memory blocks B8 to B11 of the circuit chips C0 to C8, and the divided region 240 includes a group of respective memory blocks B12 to B15 of the circuit chips C0 to C8.

In the present embodiment, the plurality of stacked circuit chips C0 to C8 may include memory blocks determined to be defective when tested. Therefore, at least one of the group of memory blocks includes at least one memory block determined to be defective, and a predetermined number (for example, the number of memory blocks required as a product) or more of memory blocks determined to be non-defective. Thus, the number of circuit chips (for example, m+1) in the three-dimensional device 50 is such that the number of memory blocks is larger than the number of memory blocks required as a product (for example, the number n of memory blocks per circuit chip x the number m of circuit chips to be stacked). Therefore, in the present embodiment, the interconnect portion 110 is communicatively connected, for each group of memory blocks included in each of the divided regions overlapping in a stacking direction in the plurality of circuit chips C0 to C8, to a predetermined number (for example, the number being less than the number of the memory blocks included in each divided region) of memory blocks sorted from the memory blocks within the group. Note that, in the present embodiment, as an example, the number of memory blocks required as a product is 32 in each divided region 210 to 240.

Note that, the plurality of stacked circuit chips C0 to C8 of the present embodiment may include at least one circuit chip including at least one memory block determined to be defective. Therefore, some of the divided region may not include defective memory blocks. Next, the connection between the interconnect portion 110 and the memory block will be described in detail.

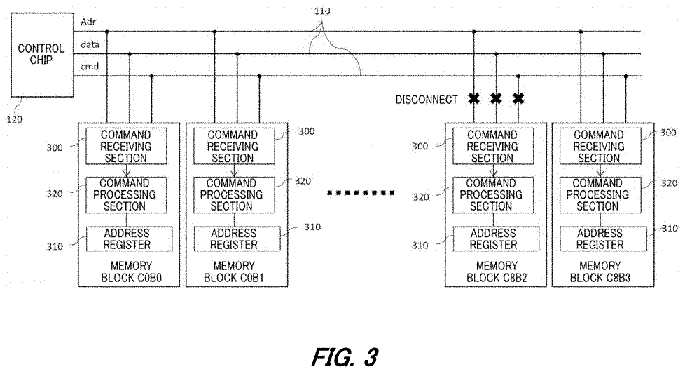

FIG. 3 shows one example of a circuit configuration of a three-dimensional device 50 of the present embodiment. FIG. 3 shows the connection of the interconnect portion 110 in one of the divided regions 210, as an example. The divided regions 220 to 240 may be similar to the divided region 210. Note that, in FIG. 3, before the reference number of the memory blocks, the reference number of the circuit chips on which said memory blocks are formed is indicated. In the embodiment in FIG. 3, the plurality of memory blocks C0B0 to C8B3 each includes a command receiving section 300, an address register 310, and a command processing section 320.

The command receiving section 300 is connected to the command processing section 320, and receives a command from the control chip 120 via the interconnect portion 110.

The address register 310 is connected to the command processing section 320, and sets an address associated with each of the plurality of memory blocks C0B0 to C8B3. The address register 310 may have an address set by the processor 20 when the apparatus 10 is turned on or at the time of initialization. The address setting corresponding to the memory block in the address register 310 is rewritable by means of the processor 20. For a memory block determined to be non-defective from the testing of circuit chips upon manufacturing of the three-dimensional device 50, for example, an address may be written to the address register 310 by the processor 20. In a case where a memory block is determined to be defective in its connection or the like from the testing after the address for the memory block has been written to the address register 310 (for example after manufacturing or the like), the address setting may further be rewritten, an address corresponding to said memory block may be deleted, or the like. In this case, the control chip 120 may set a corresponding address to another non-defective memory block that does not yet have an address set, in the same divided region as the memory block of the deleted address. Note that, the address register 310 may have a flag set by means of the processor 20, indicating that the memory block should not be used for defective memory blocks connected to the interconnect portion 110.

The command processing section 320 executes a process specified by a command, in response to the command receiving section 300 receiving the command. When the address received from the address line (Adr) and the address stored in the address register 310 matches, the command processing section 320 may write data received from the data line (data) or transmit data to the data line (data), according to the command (write command or read command) received from the command line (cmd).

In FIG. 3, the memory block C8B2 (the memory block B2 of the circuit chip C8) is a memory block determined to be defective at the testing. In the present embodiment, at least one memory block C8B2 determined to be defective is disconnected from at least one of the interconnect portion 110 and the power source. Note that, in the divided region 210, 32 out of 36 memory blocks may be connected to the interconnect portion 110, and the other four memory blocks may be disconnected.

In addition, when there is more non-defective memory blocks in the divided region 210 than the number of memory blocks required as a product (32 in the present embodiment), the interconnect portion 110 may connect to more non-defective memory blocks than the required number. In this case, the excess of non-defective memory blocks may be replacement for failed memory blocks or future failure, or may store ECC (Error Check and Correct) bits. In this manner, ECC bit for preventing memory malfunction can be provided without increasing the size of the circuit chip.

Note that, defective memory blocks (for example, the memory block C8B2) may not form the command receiving section 300, the address register 310, and the command processing section 320.

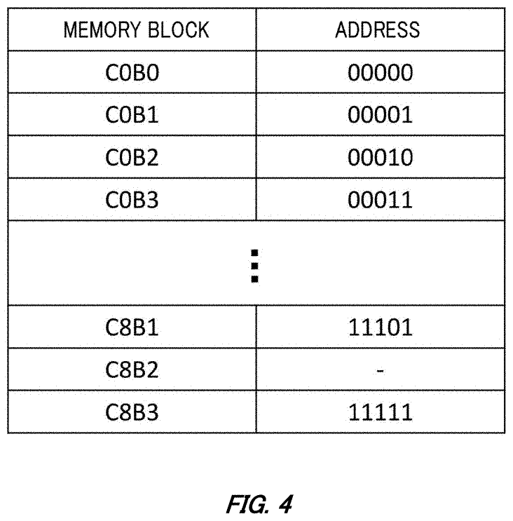

FIG. 4 shows one example of a correspondence table of memory blocks C0B0 to C8B3 and addresses. The addresses in the correspondence table may each be stored in the address register 310 of a corresponding memory block. The memory block connected to the interconnect portion 110 may have an address (of 5 bits, for example) corresponding to respective memory blocks for each of the divided regions set in the address register 310 by the processor 20, as shown in FIG. 4. The address register 310 may further have an address (of 2 bits, for example) of a corresponding divided region set by the processor 20. Here, the memory block C8B2 may not be connected to the interconnect portion 110 and not have an address set therein.

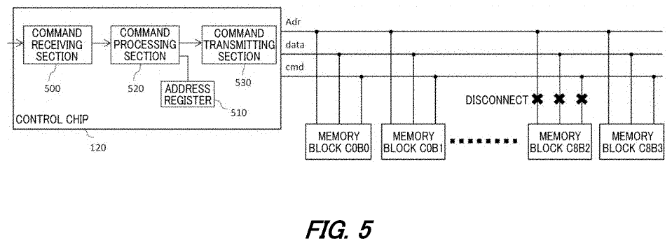

FIG. 5 is an illustration showing another example of the three-dimensional device 50 of the present embodiment. FIG. 5 shows the connection of the interconnect portion 110 in one divided region 210, as an example. The embodiment of FIG. 5 differs from the embodiment of FIG. 3 in that instead of the memory blocks C0B0 to C8B3, the control chip 120 holds the address of each memory block C0B0 to C8B3. For other configurations, the embodiment of FIG. 5 may be similar to the embodiment of FIG. 3.

The control chip 120 includes a command receiving section 500, an address register 510, a command processing section 520, and a command transmitting section 530. The command receiving section 500 is connected to the command processing section 520, and receives, from the processor 20, a command including a specification of an address for the three-dimensional device 50. The address register 510 is connected to the command processing section 520, and sets an address associated with each of the plurality of memory blocks C0B0 to C8B3. The address register 510 may store a correspondence table showing the correspondence between the memory blocks C0B0 to C8B3 and their addresses, as shown in FIG. 4, for example. The command processing section 520 is connected to the command transmitting section 530. The command processing section 520 accesses a memory block associated with an address specified by the command, in response to the command receiving section 500 receiving the command. For example, according to the command (write command or read command) received from the processor 20, the control chip 120 writes, to the specified address in the memory block C0B3 associated with the address (00011) specified in the command, the data transmitted via the data line (data), or reads data from the address of said memory block C0B3 via the data line (data). The command transmitting section 530 transmits the data and command from the command processing section 520 to each of the memory blocks C0B0 to C8B3.

According to the present embodiment, the three-dimensional device 50 includes a redundant memory block in the divided region in the stacking direction of the circuit chip 100, thereby a required number of non-defective memory blocks can be connected to the interconnect portion 110 for each of the divided regions even when a circuit chip including defective memory blocks are used. Therefore, the yield of the three-dimensional device 50 is improved. Although the yield may be lowered by additional circuit chips 100 to be stacked, the improvement due to the use of a circuit chip 100 including a defective memory block for a product may be further increased. Since the wiring distance between circuit chips 100 can be reduced to be smaller than the wiring distance within the plane of the circuit chip 100, wiring can be efficiently formed by adjusting the number of non-defective memory blocks connecting to the interconnect portion 110 in the stacking direction.

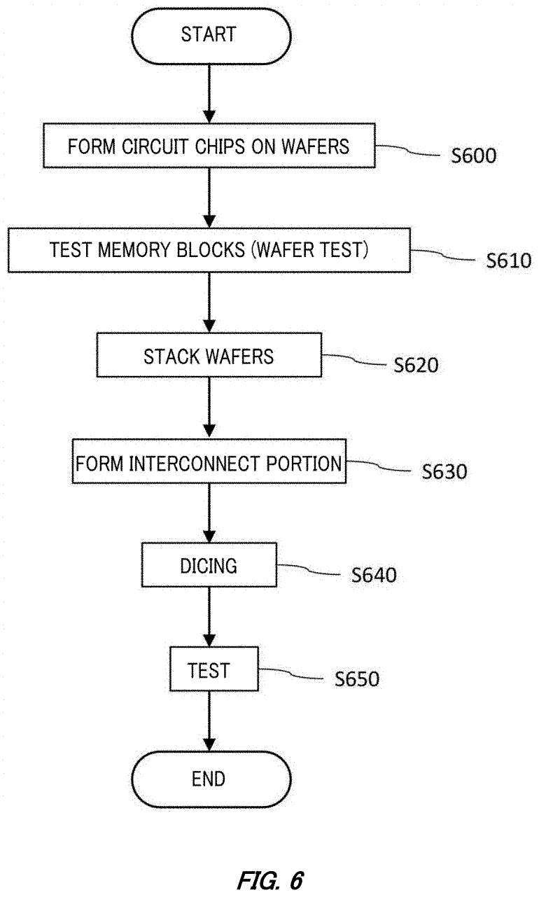

FIG. 6 shows a manufacturing flow for the three-dimensional device 50 of the present embodiment. At S600, a wafer having arranged thereon circuit chip regions each having one or more memory blocks in each of a plurality of divided regions 210 to 240 obtained by dividing a circuit plane 200 is formed by means of a circuit forming apparatus. A plurality of circuit chip regions may be formed respectively on the surface of a plurality of wafers. Each circuit chip region may be DRAM (Dynamic Random Access Memory), SRAM (Static Random Access Memory), flash memory, or the like, and may include a plurality of memory blocks.

At S610, the memory blocks on the wafer are each tested by a test apparatus. The test may be a burn-in test or the like, for example The test may examine whether the memory block operates normally, and may determine the memory block to be non-defective if it operates normally and defective if it does not operate normally. The test apparatus to perform the test may store, for each wafer, the number, location, identifier, or the like of memory blocks determined to be defective. Wafers determined to include a number of defective memory blocks that is equal to or less than a threshold at this step is used at the next step, whereas wafers determined to include a number of defective memory blocks that is more than the threshold is not used at the next step, and may be discarded or the like. Note that, whether the threshold is exceeded may be determined for each circuit chip region, or each of the divided regions. Note that, at S610, determination on whether the memory block is defective or non-defective may be performed with data retrieved in advance (for example, data retrieved during previous steps) without performing a test, or determination on whether the memory block is defective or non-defective may be performed with the data retrieved in advance and test results of the test apparatus.

At S620, a plurality of wafers is stacked with a stacking apparatus. The step of stacking a plurality of wafers includes a step of selecting a combination of the wafers to be stacked based on the number of the three-dimensional devices 50 in which at least a predetermined number of memory blocks determined to be non-defective by the test are stacked, for each group of memory blocks included in each of the divided regions 210 to 240 overlapping in the stacking direction based on a location in the wafer of the memory blocks determined to be non-defective by the test. For example, when stacked, in a group of each of the divided regions, a combination of wafers where the number of three-dimensional devices 50 in which at least a predetermined number (at least 32 in the present embodiment) of memory blocks determined to be non-defective by the test are stacked becomes equal to or more than the threshold or at a maximum is selected by the stacking apparatus. The stacking apparatus may receive information on defective memory blocks (number, location, identifier, or the like) from the test apparatus used at S610, and use the information to select a combination of wafers.

The stacking apparatus may select a combination of wafers to be stacked based on at least one of the size of the divided region (for example, the number of memory blocks included in one divided region), and the size of the memory block (for example, the number of memory elements included in one memory block). The stacking apparatus may select a combination of wafers, by changing at least one of the size of the divided region and the size of the memory block. In this way, three-dimensional devices 50 can be manufactured as much as possible.

At s620, the stacking apparatus may stack a wafer having a control chip 120 formed thereon at the lower end of the stacked wafers. The plurality of wafers may be stacked via at least one of a microbump, through wiring 115, or the like. At S620, after the plurality of wafers are stacked, a through hole passing through the plurality of wafers may be created with electron beam or the like, and through wiring 115 of the interconnect portion 110 may be formed by melting and filling conductive metal such as solder into the through hole.

At S630, before the step of dicing, the connection apparatus forms an interconnect portion 110 communicatively connected, for each group of memory blocks included in each of the divided regions 210 to 240 (or respective divided regions adjusted at S620) overlapping in the stacking direction, to a predetermined number of memory blocks sorted from among the memory blocks in the group based on the test result at S610. For example, in the memory blocks determined to be non-defective by the test, the connection apparatus may connect a number of memory blocks required as a product and the interconnect portion 110, for each of the divided regions 210 to 240. In addition, after connecting all of the memory blocks and the interconnect portion 110 with wiring, the connection apparatus may disconnect only the memory blocks determined to be defective by the test. For example, the disconnection may include cutting a fuse of the memory block determined to be defective with electron beam or the like. In addition, the connection apparatus may not form connection wiring with the memory blocks determined to be defective by the test.

At S640, a dicing apparatus dices a plurality of stacked wafer in each circuit chip region and creates chips to form a plurality of stacked circuit chips 100.

At S650, the testing apparatus may test the stacked circuit chips 100. For example, the testing apparatus may perform tests such as a speed test, a test for wiring of the interconnect portion 110, or the like. Circuit chips 100 determined to be non-defective in the test may become a product of the three-dimensional device 50. At S650, the processor 20 or the testing apparatus may set an address of each memory block in the address register.

According to the present embodiment, wafers including memory blocks determined to be defective can be used for manufacturing a product and the yield can be improved.

Note that, the step S630 of forming the interconnect portion 110 may be performed after the dicing step S640. In addition, the dicing step S640 may be performed before the stacking step S620. In this case, the testing step S610 may be performed on each circuit chip 100 between the dicing step S640 and the stacking step S620. Setting the address in the address register may be performed at any steps after the testing of memory blocks. In addition, the control chip 120 may be placed for each circuit chip 100, and may be placed on the top surface of a plurality of stacked circuit chips 100 (for example, on the top surface of the uppermost circuit chip 100).

Note that, although the three-dimensional device of the present application is described as a memory portion of an HBM device in the present embodiment, the three-dimensional device of the present application may include circuit blocks other than memory blocks, which may be a 3D DRAM, a cache memory used for a MPU (Micro Processor Unit) or the like, a three-dimensional stacked multi-core processor with stacked processors or the like, or the like may be included. In addition, the three-dimensional device of the present application may include circuit chips 100 of which all the memory blocks are determined to be non-defective.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A three-dimensional device comprising:
a plurality of stacked circuit chips each having one or more circuit blocks in each of a plurality of divided region obtained by dividing a circuit plane; and
an interconnect portion communicatively connected, for each group of circuit blocks included in each of the divided regions overlapping in a stacking direction in the plurality of circuit chips, to a predetermined number of circuit blocks sorted from the circuit blocks within the group.

2. The three-dimensional device according to claim 1, wherein
the interconnect portion includes through wiring which passes through at least one circuit chip and extends in the stacking direction of the plurality of circuit chips.

3. The three-dimensional device according to claim 1, wherein
at least one of the groups of circuit blocks includes at least one circuit block determined to be defective, and the predetermined number of circuit blocks determined to be non-defective.

4. The three-dimensional device according to claim 3, wherein
the at least one circuit block determined to be defective is disconnected from at least one of the interconnect portion and a power source.

5. The three-dimensional device according to claim 1, comprising
a control chip being connected to the interconnect portion below or above the circuit chip that is configured to control each circuit block.

6. The three-dimensional device, according to claim 5, wherein the control chip includes:
an address register configured to set an address associated with each of the plurality of circuit blocks;
a command receiving section configured to receive a command including specification of an address for the three-dimensional device; and
a command processing section configured to access the circuit block associated with the address specified by the command, in response to receiving the command.

7. The three-dimensional device according to claim 1, wherein each of the plurality of circuit blocks includes:
an address register configured to set an address associated with each of the plurality of circuit blocks;
a command receiving section configured to receive a command via the interconnect portion; and
a command processing section for executing a process specified by the command, in response to receiving the command.

8. The three-dimensional device according to claim 6, wherein
an address setting corresponding to the circuit block in the address register is rewritable.

9. The three-dimensional device according to claim 1, wherein
each of the plurality of circuit blocks is a memory block.

10. A manufacturing method for a three-dimensional device, comprising:
forming a wafer having arranged thereon a circuit chip region with one or more circuit blocks in each of a plurality of divided regions obtained by dividing a circuit plane;
testing each of the circuit blocks on the wafer;
stacking a plurality of the wafers; forming a plurality of stacked circuit chips by dicing the plurality of stacked wafers in each circuit chip region; and
before or after the dicing, forming an interconnect portion communicatively connected, for each group of circuit blocks included in each of the divided regions overlapping in a stacking direction, to a predetermined number of circuit blocks sorted from the circuit blocks within the group based on a result of the test.

11. The manufacturing method according to claim 10, wherein
stacking the plurality of wafers include selecting a combination of the wafers to be stacked, based on the number of the three-dimensional devices in which at least the predetermined number of circuit blocks determined to be non-defective by the test are stacked, for each group of circuit blocks included in each of the divided regions overlapping in a stacking direction, based on a location in the wafer of the circuit block determined to be non-defective by the test.
